(19) United States
(12) Patent Application Publication
(10) Pub. No.: US 2025/0218879 A1
(43) Pub. Date: Jul. 3, 2025

(54) RESIST TENTING AND PLATING IN CORE CAVITY FOR COMPONENT ATTACHMENT

(71) Applicant: Intel Corporation, Santa Clara, CA (US)

(72) Inventors: Hiroki TANAKA, Gilbert, AZ (US); Kyle MCELHINNY, Tempe, AZ (US); Robert Alan MAY, Chandler, AZ (US); Bai NIE, Chandler, AZ (US); Bohan SHAN, Chandler, AZ (US); Srinivas Venkata Ramanuja PIETAMBARAM, Chandler, AZ (US); Gang DUAN, Chandler, AZ (US)

(21) Appl. No.: 18/400,395

(22) Filed: Dec. 29, 2023

(51) Int. Cl. H01L 23/13; H01L 23/00; H01L 23/14; H01L 23/48; H01L 23/498

(52) U.S. Cl. CPC H01L 23/13; H01L 23/14; H01L 23/481; H01L 23/49822; H01L 24/16; H01L 2224/16225; H01L 2924/19011

(57) ABSTRACT

Embodiments disclosed herein include components that are embedded within a core of a package substrate. In an embodiment, the component is supported on a pad provided at a bottom of a cavity through the core. In an embodiment, such an apparatus may comprise a substrate with a cavity through a thickness of the substrate. In an embodiment, the cavity comprises sidewalls. In an embodiment, a layer spans an opening of the cavity, and the layer covers at least a portion of the sidewalls of the cavity. In an embodiment, a component is coupled to the layer, and the component is at least partially within the cavity.

### BACKGROUND

As advanced packaging is enabling more aggressive computation capability, high power and high quality power delivery is needed to support all of the overlying chiplets. The ability to embed passive components (e.g., capacitors, inductors, resistors, etc.) into the package substrate will enable improved performance compared to placing the passive components on the land side of the package. Embedding components in the core is beneficial because there is less routing in the core compared to overlying and underlying buildup layers. As such, space within the package substrate is more fully utilized.

However, substrate core thickness is defined by the total package thermomechanical stress level. This required thickness can be significantly different than the thickness of the passive component. For example, in the case of a deep trench capacitor (DTC), the DTC is fabricated on a silicon wafer. The wafer will have a thickness that is potentially hundreds of microns different than the thickness of the core, which can be approximately 1.0 mm or greater. Placing such passive components in deep cavities through the core can be problematic. For example, the passive components may shift or rotate during embedding.

### BRIEF DESCRIPTION OF THE DRAWINGS

FIG. 1 is a cross-sectional illustration of a core with an embedded passive component that has shifted during the embedding process, in accordance with an embodiment.

FIG. 2A is a cross-sectional illustration of a portion of a package substrate with a component over a layer where both are embedded in a core, in accordance with an embodiment.

FIG. 2B is a cross-sectional illustration of a portion of a package substrate with a component over a layer where both are embedded in a core, in accordance with an additional embodiment.

FIG. 2C is a cross-sectional illustration of a portion of a package substrate with a pair of components over a layer and all elements are embedded in a core, in accordance with an embodiment.

FIGS. 3A-3O are cross-sectional illustrations depicting a process for forming a package substrate with a component that is supported by a layer within a cavity in a core of the package substrate, in accordance with an embodiment.

FIG. 3P is a process flow diagram of a process for embedding a component in a cavity of a package substrate using a tenting process, in accordance with an embodiment.

FIG. 4 is a cross-sectional illustration of an electronic system that comprises a package substrate with a component embedded in a core of the package substrate, in accordance with an embodiment.

FIG. 5 is a schematic of a computing device built in accordance with an embodiment.

### EMBODIMENTS OF THE PRESENT DISCLOSURE

Described herein are electronic systems, and more particularly, cavities in package substrate cores that have plated layers on which components are supported, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

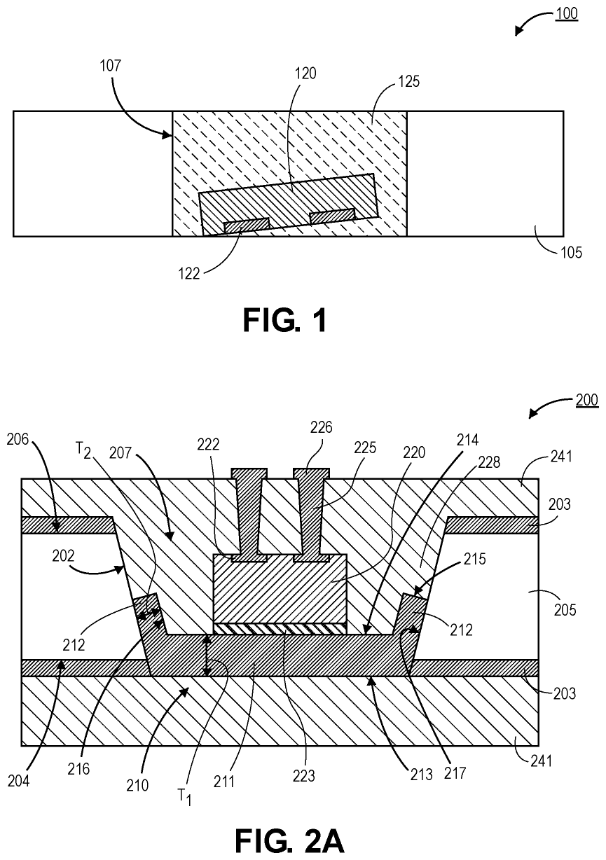

As noted above, introducing passive components (e.g., inductors, capacitors, resistors, etc.) into the package substrate is desirable to improve power delivery and performance for the overlying chiplets compared to placing the passive components on the land side of the package substrate. This is due, at least in part, to the passive components being physically closer to the chiplets when they are integrated into the package substrate. One suitable location in the package substrate for the passive components is the core. The core has underutilized space that can be leveraged to house the passive components. However, the thickness of the passive components is usually smaller than a thickness of the core. This can lead to integration and manufacturing issues. Examples of these drawbacks can be seen in FIG. 1.

Referring now to FIG. 1, a cross-sectional illustration of a portion of a package substrate 100 is shown, in accordance with an embodiment. The package substrate 100 may comprise a core 105. The core 105 may sometimes be referred to simply as a substrate. The core 105 may be a glass core, an organic core, or the like. In an embodiment, a cavity 107 passes at least partially through the core 105. For example, in FIG. 1 the cavity 107 passes entirely through the core 105.

In an embodiment, a component 120 is provided in the cavity 107. The component 120 may have a thickness that is smaller than a thickness of the core 105. For example, the component 120 may have a thickness that is hundreds of microns thinner than the core 105. The component 120 is secured within the cavity 107 through the use of a fill layer 125. The fill layer 125 may be a dielectric material, such as a mold layer, an epoxy, an adhesive, or the like. However, during the filling process, the component 120 may shift and/or rotate. The movement of the component 120 may be due, at least in part, to the introduction of pressure to the component 120 during the filling process. As shown, the component 120 has tilted so that one side is raised up from the bottom of the core 105. This may make it difficult to make electrical contact to the pads 122 that are at the bottom of the component 120 in subsequent processing operations.

Accordingly, embodiments disclosed herein reduce movement of the electrically passive component by supporting the component on a plated layer at a bottom of a cavity through a core. The plated layer may be preferentially located at the bottom of the cavity through the use of a tenting lithography process. For example, a resist may be applied across the opening of the cavity. A portion of the resist will extend into an upper region of the cavity without fully filling the cavity. A patterning process provides an opening through the resist to expose a bottom of the cavity. In an embodiment, a plating process is then used to plate only at a bottom region of the cavity.

In an embodiment, the plating process may result in the formation of a layer that has a bowl shaped cross-section. As used herein, a bowl shaped cross-section may refer to a layer that has a central first region with second regions that extend up away from the first region. The central first region may have top and bottom surfaces that are substantially horizontal, and the second regions may have surfaces that extend away from the central first region at an angle (e.g., between approximately 10° and approximately 90°). More generally, the layer may conform to sidewalls of the cavity.

In an embodiment, the component is placed on the layer. This raises the component up towards the top surface of the core. As such, a thickness mismatch between a thickness of the core and a thickness of the component is reduced or eliminated. Subsequent embedding is made easier, and is less likely to displace the component. Additionally, vias to the component may be shorter and easier to fabricate.

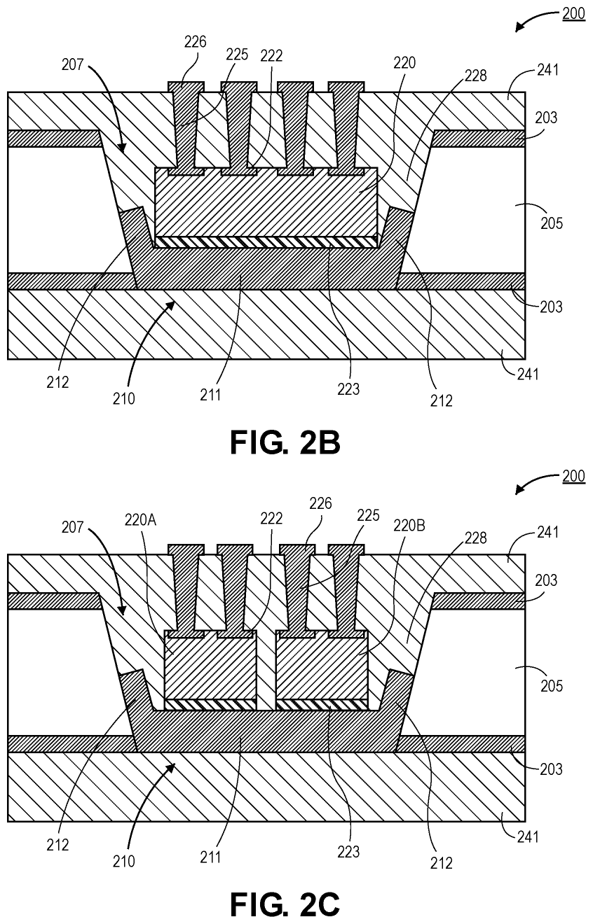

Referring now to FIG. 2A, a cross-sectional illustration of a portion of a package substrate 200 is shown, in accordance with an embodiment. In an embodiment, the package substrate 200 may comprise a core 205. The core 205 may be an organic core 205 or a glass core 205. In the case of a glass core 205, the glass core 205 may be substantially all glass. The glass core 205 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, glass core 205 may be distinguished from, for example, the “prepreg” or “RF4” core of a Printed Circuit Board (PCB) substrate which typically comprises glass fibers embedded in a resinous organic material, such as an epoxy.

The glass core 205 may have any suitable dimensions. In a particular embodiment, the glass core 205 may have a thickness that is approximately 50 μm or greater. For example, the thickness of the glass core 205 may be between approximately 50 μm and approximately 1.4 mm. Though, smaller or larger thicknesses may also be used. The glass core 205 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core 205 (from an overhead plan view) may be between approximately 10 mm×10 mm and approximately 250 mm×250 mm. In an embodiment, the glass core 205 may have a first side that is perpendicular or orthogonal to a second side. In a more general embodiment, the glass core 205 may comprise a rectangular prism volume with sections (e.g., vias) removed and filled with other materials (e.g., metal, etc.).

The glass core 205 may comprise a single monolithic layer of glass. In other embodiments, the glass core 205 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 205 may each have a thickness less than approximately 50 μm. For example, discrete layers of glass in the glass core 205 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core 205 may be any suitable glass formulation that has the necessary mechanical robustness and compatibility with semiconductor packaging manufacturing and assembly processes. For example, the glass core 205 may comprise aluminosilicate glass, borosilicate glass, alumino-borosilicate glass, silica, fused silica, or the like. In some embodiments, the glass core 205 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 205 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 205 may comprise at least 23 percent silicon (by weight) and at least 26 percent oxygen (by weight). In some embodiments, the glass core 205 may further comprise at least 5 percent aluminum (by weight).

In an embodiment, cladding 203 may be provided over and/or under the core 205. The cladding 203 may comprise electrically conductive material, such as copper or the like. In an embodiment, the cladding 203 may be omitted. Vias (not shown) or other electrically conductive routing may also be provided through and/or on the core 205.

In an embodiment, a cavity 207 may be formed through a thickness of the core 205. In the illustrated embodiment, the cavity 207 includes sloped sidewalls 202. Accordingly, a top opening of the cavity 207 may be wider than a bottom opening of the cavity 207. Though, in other embodiments the sidewalls 202 may be substantially vertical. The cavity 207 may be formed through any suitable processing operation, depending on the material composition of the core 205.

In an embodiment, a spacer layer 210 may be provided at a bottom of the cavity 207. The spacer layer 210 may comprise an electrically conductive material. For example, the spacer layer 210 may comprise copper or the like. In some embodiments, the spacer layer 210 is formed through a plating process. That is, the spacer layer 210 may be provided over a seed layer (not shown in FIG. 2A). Though, other deposition processes may also be used in some embodiments. While metallic materials may be used as one option for the spacer layer 210, it is to be appreciated that other material classes may also be used as the spacer layer 210. For example, ceramics, glasses, organic dielectrics, or the like may also be used in some embodiments.

In an embodiment, the spacer layer 210 may comprise a first portion 211 and second portions 212. The first portion 211 may span across the bottom opening of the cavity 207 (e.g., the first portion 211 may seal the bottom opening of the cavity 207), and the second portions 212 may extend up the sidewalls 202 of the cavity 207. In some embodiments, the top surface 214 and/or the bottom surface 213 of the first portion 211 may be substantially parallel to a top surface 206 and/or a bottom surface 204 of the core 205. The second portions 212 may have surfaces 216 and 217 that are along planes that intersect planes comprising the top surface 206 and/or the bottom surface 204 of the core 205. For example, the angle of intersection between the planes may be between approximately 10° and approximately 90°. In some embodiments, the spacer layer 210 may be considered as having a bowl shaped cross-section.

In an embodiment, the second portions 212 may extend up the sidewalls 202 of the cavity 207. Generally, the top surfaces 215 of the second portions 212 are located below the upper opening of the cavity 207. For example, the top surface 215 may extend up to approximately 75% of the height of the sidewall 202, up to approximately 50% of the height of the sidewall 202, up to approximately 25% of the height of the sidewall 202, or up to approximately 10% of the height of the sidewall 202.

In an embodiment, the first portion 211 may have a first thickness T₁ and the second portions 212 may have a second thickness T₂. The first thickness T₁ may be a distance between the bottom surface 213 and the top surface 214 along a line that is orthogonal to the bottom surface 213. The second thickness T₂ may be a distance between the surface 217 and the surface 216 along a line that is orthogonal to the surface 217. The second thickness T₂ may be smaller than the first thickness T₁. Though, in other embodiments, the second thickness T₂ may be approximately equal to the first thickness T₁, or the second thickness T₂ may be greater than the first thickness T₁.

In an embodiment, a component 220 is coupled to the spacer layer 210. Particularly, the component 220 may be coupled to the top surface 214 of the first portion 211 of the spacer layer 210. In an embodiment, an adhesive 223 may couple the component 220 to the spacer layer 210. The adhesive 223 may be a die bonding film (DBF) or the like. In an embodiment, the component 220 may be an electrically passive component. For example, the component 220 may comprise one or more of an inductor, a capacitor, a resistor, or the like. In a particular embodiment, the component 220 is a deep trench capacitor (DTC). The component 220 may comprise a substrate, such as a silicon substrate. Though, other materials may also be used as the substrate of the component 220 (e.g., glass, ceramic, organic dielectric, or other material classes). In the illustrated embodiment, the component 220 is shown as a monolithic layer. However, it is to be appreciated that electrical routing (e.g., pads, traces, vias, electrodes, plates, etc.), dielectric materials (e.g., high-k dielectrics for capacitors), magnetic material (e.g., for inductors), and other structures to enable passive electrical elements may be present within or on the component 220. In an embodiment, pads 222 may be provided on the component 220 in order to electrically couple the component 220 to other devices (e.g., dies (not shown)) through vias 225, pads 226, traces, etc.

In an embodiment, the component 220 has a thickness that is smaller than a thickness of the core 205. The spacer layer 210 raises the component 220 up towards the top surface 206 of the core 205. In an embodiment, the top of the component 220 is substantially coplanar with the top surface 206 of the core 205. Though, the top of the component 220 may be above or below the top surface 206 of the core 205, in accordance with other embodiments.

In an embodiment, a first distance between an uppermost point of the top surface 215 of the second portion 212 of the spacer layer 210 and a plane comprising the top surface 206 of the core 205 is larger than a second distance between a top surface of the component 220 and the plane comprising the top surface 206 of the core 205. That is, the top of the component 220 is above the spacer layer 210. In some embodiments, a third distance between a bottom of the component 220 and the plane comprising the top surface 206 of the core 205 may be larger than the first distance. Accordingly, the second portion 212 of the spacer layer 210 may overlap a portion of a sidewall of the component 220 in some embodiments. In the illustrated embodiment, the sidewall of the component 220 is spaced away from the second portion 212 of the spacer layer 210. That is, a width of the first portion 211 of the spacer layer 210 may be wider than a width of the component 220.

In an embodiment, a fill layer 228 may fill a remainder of the cavity 207. The fill layer 228 may be an organic dielectric material, such as a buildup film. In an embodiment, the fill layer 228 may be disposed on the package substrate 200 with a lamination process, or the like. In an embodiment, the fill layer 228 may be part of the buildup layers 241 that are provided over and/or under the core 205. That is, the fill layer 228 and the buildup layers 241 may be laminated onto the core 205 with a single lamination process in some embodiments.

Referring now to FIG. 2B, a cross-sectional illustration of a portion of a package substrate 200 is shown, in accordance with an additional embodiment. The package substrate 200 in FIG. 2B may be similar to the package substrate 200 in FIG. 2A, with the exception of the structure of the spacer layer 210 and the component 220. For example, a width of the component 220 may be substantially equal to a width of the upper surface of the first portion 211 of the spacer layer 210. In such an embodiment, the adhesive 223 and/or the component 220 may contact the second portion 212 of the spacer layer 210. Reducing the spacing between the second portion 212 and the component 220 may further reduce displacement or movement of the component 220 during embedding processes.

Referring now to FIG. 2C, a cross-sectional illustration of a portion of a package substrate 200 is shown, in accordance with an additional embodiment. The package substrate 200 in FIG. 2C may be similar to the package substrate 200 in FIG. 2A, with the exception of there being a plurality of components 220 supported on the spacer layer 210. For example, a first component 220A and a second component 220B may be coupled to the spacer layer 210. The first component 220A and the second component 220B may be similar to each other. Though, in other embodiments different types of components 220 may be embedded within a single cavity 207. Increasing the number of components 220 may provide increased capacity (e.g., more inductance, capacitance, resistance, etc.) in order to better control power delivery. While two components 220A and 220B are shown in FIG. 2C, it is to be appreciated that any number of components 220 may be embedded within a single cavity 207.

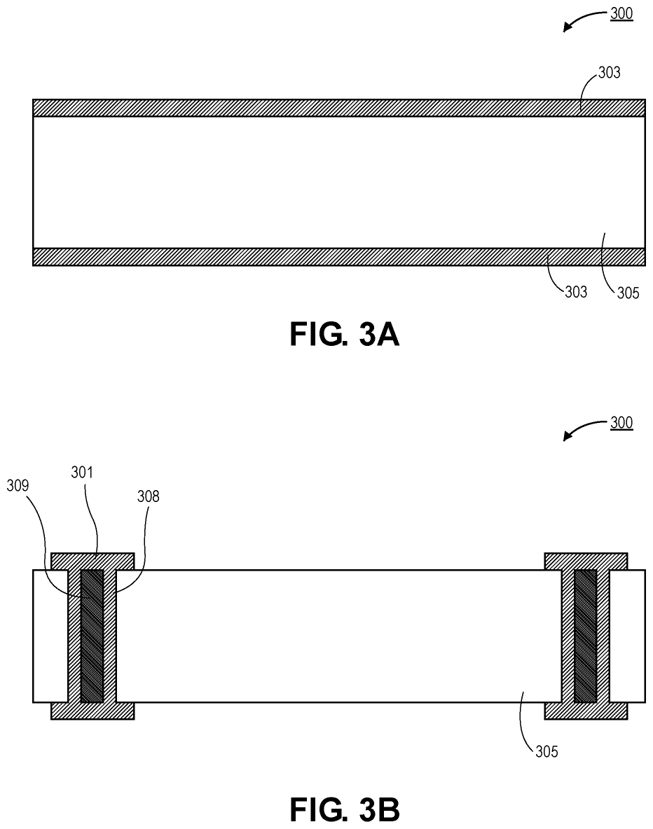

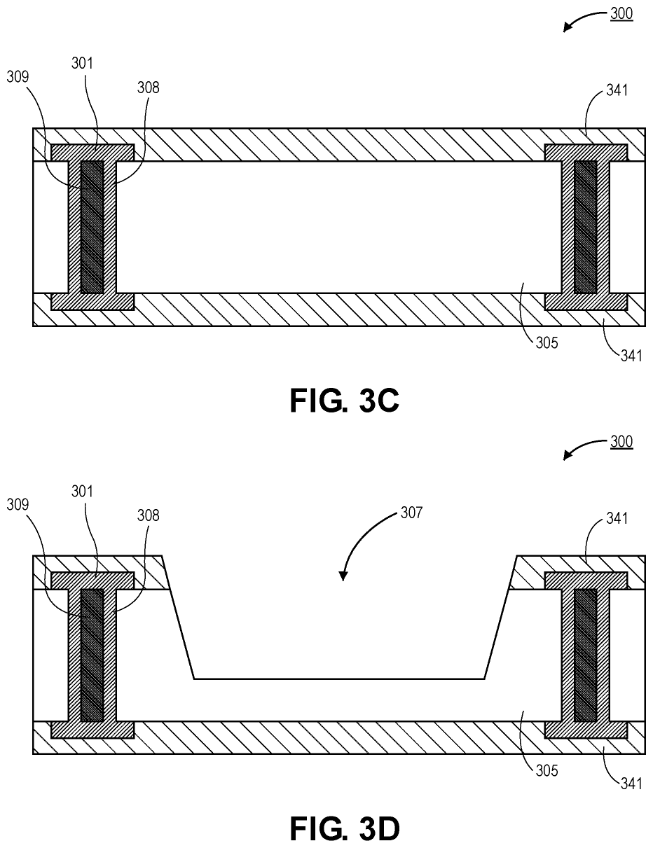

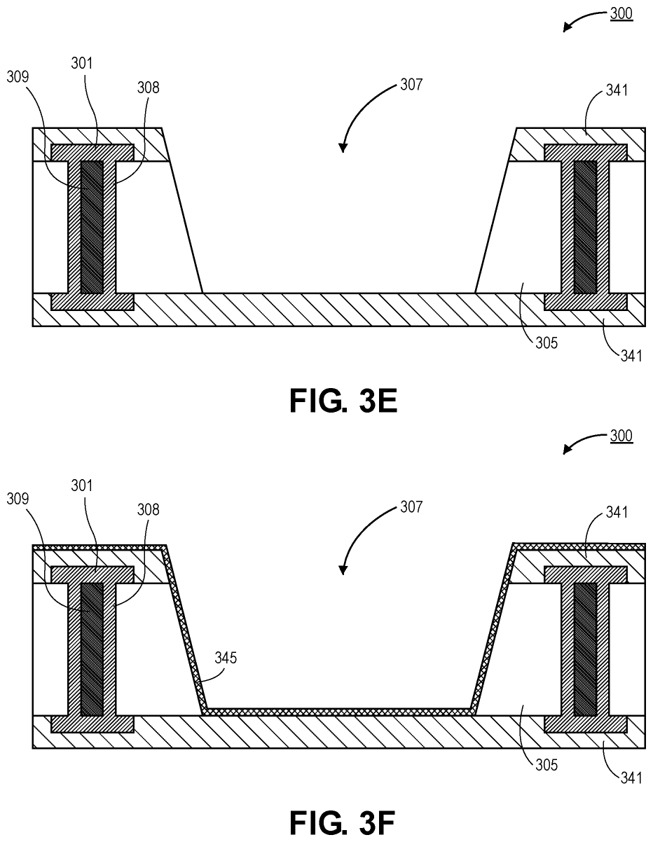

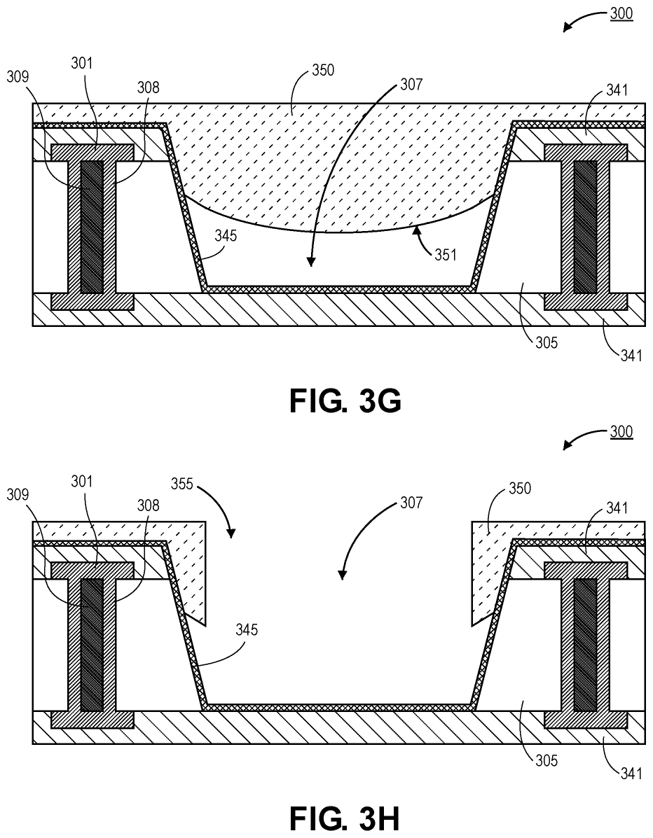

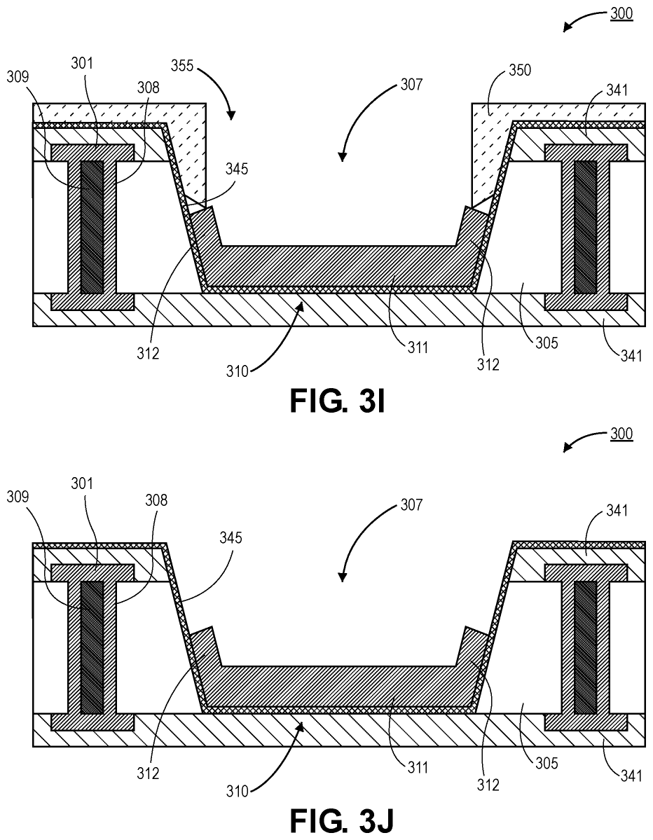

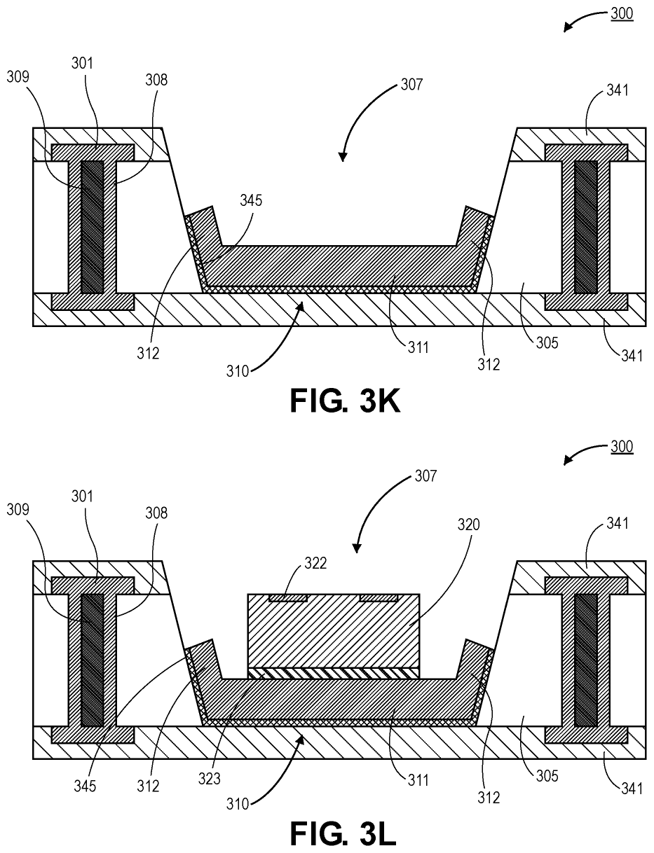

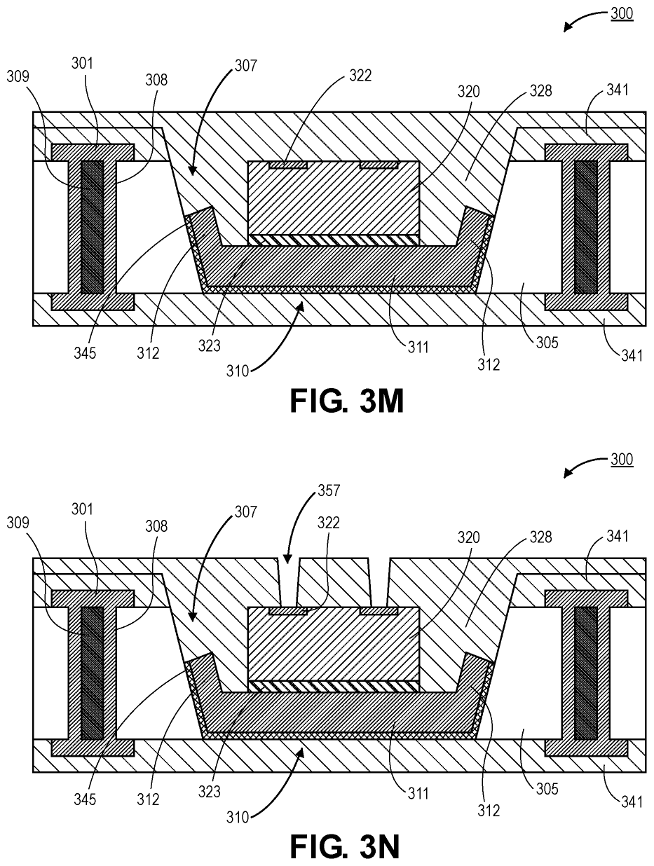

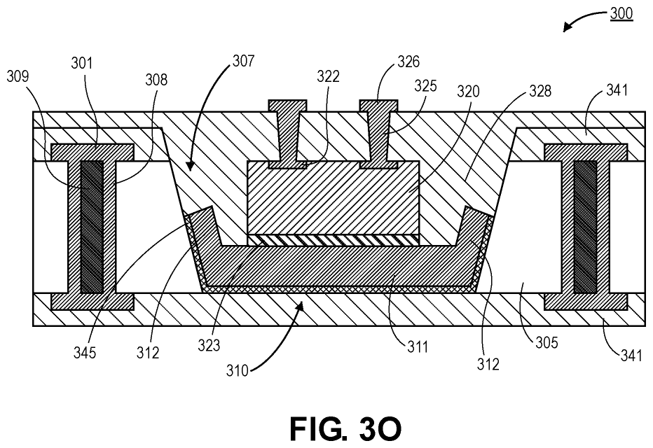

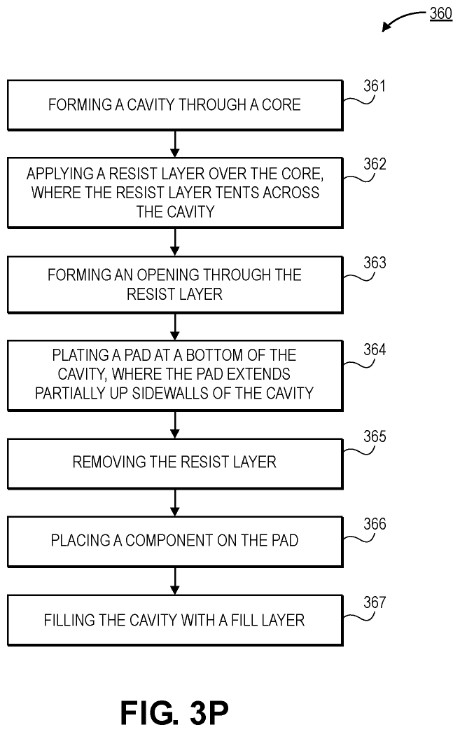

Referring now to FIGS. 3A-3O, a series of cross-sectional illustrations depicting a process for forming a package substrate 300 is shown, in accordance with an embodiment. In the embodiments shown, a tenting process is used in order to selectively form a spacer layer 310 at the bottom of a cavity 307 through the core 305. A component 320 can then be supported on the spacer layer 310 in order to raise the height of the component 320 within the cavity 307.

Referring now to FIG. 3A, a cross-sectional illustration of a portion of a package substrate 300 is shown, in accordance with an embodiment. As shown, the package substrate 300 may comprise a core 305. The core 305 may be an organic core 305, a glass core 305, or the like. More generally, core 305 may be similar to any of the cores described in greater detail herein. In an embodiment, cladding layers 303 may be provided over and/or under the core 305. The cladding layers 303 may comprise an electrically conductive material, such as copper or the like.

Referring now to FIG. 3B, a cross-sectional illustration of the portion of the package substrate 300 after vias 308 are formed is shown, in accordance with an embodiment. The vias 308 may pass through a thickness of the core 305. In an embodiment, the vias 308 may comprise an electrically conductive material, such as copper or the like. In the illustrated embodiment, the vias 308 include a plated through hole (PTH) configuration. That is, the vias 308 may be a shell that is filled with an insulating plug 309. Though, in other embodiments, the vias 308 may be fully filled with an electrically conductive material. While shown as having vertical sidewalls, in some embodiments the vias 308 may have tapered or otherwise sloped sidewalls. Pads 301 may be provided over and/or under the vias 308 in some embodiments. For example, the pads 301 may be fabricated from the cladding layers 303.

Referring now to FIG. 3C, a cross-sectional illustration of the portion of the package substrate 300 after buildup layers 341 are provided over and/or under the core 305 is shown, in accordance with an embodiment. In an embodiment, the buildup layers 341 may comprise an organic dielectric layer, such as a buildup film or the like. In an embodiment, the buildup layers 341 may be applied with a lamination process or the like.

Referring now to FIG. 3D, a cross-sectional illustration of the portion of the package substrate 300 after a first portion of the cavity 307 is formed is shown, in accordance with an embodiment. In an embodiment, the first portion of the cavity 307 may extend into the core 305 to a depth that does not pass entirely through a thickness of the core 305. That is, the first portion of the cavity 307 may stop short of the bottom of the core 305. Not forming the cavity 307 entirely through the thickness of the core 305 may be useful when depth control of the cavity 307 formation process is not extremely precise. This is because it would not be desirable to pass the cavity 307 through the underlying buildup layer 341. For example, the cavity 307 formation process may include a mechanical drilling process, such as using a drill bit or a router. In the illustrated embodiment, sidewalls of the cavity 307 are sloped. Though, in other embodiments the sidewalls of the cavity 307 may be substantially vertical.

Referring now to FIG. 3E, a cross-sectional illustration of the portion of the package substrate 300 after the cavity 307 is completed is shown, in accordance with an embodiment. As shown, the cavity 307 may be extended down through an entire thickness of the core 305. The second removal process may be a more precise manufacturing operation. For example, a laser ablation process may be used in order to remove a remainder of the core 305 material at the bottom of the cavity 307. In an embodiment, the final removal process may also comprise an etching process. For example, if residual cladding 303 or seed layer material is provided along the bottom surface of the core 305, an etching process may be used to remove them. As shown, the cavity 307 may result in the exposure of the buildup layers 341 below the core 305.

Referring now to FIG. 3F, a cross-sectional illustration of the portion of the package substrate 300 after a seed layer 345 is applied is shown, in accordance with an embodiment. In an embodiment, the seed layer 345 may be provided over the top buildup layers 341, along sidewalls of the cavity 307, and along the exposed portion of the bottom buildup layers 341. The seed layer 345 may comprise any suitable electrically conductive material that can be used to initiate a plating reaction. For example, the seed layer 345 may comprise one or more of titanium, platinum, copper, or the like. In an embodiment, the seed layer 345 may be deposited with any suitable deposition process, such as atomic layer deposition (ALD), chemical vapor deposition (CVD), physical vapor deposition (PVD), or the like.

Referring now to FIG. 3G, a cross-sectional illustration of the portion of the package substrate 300 after a resist layer 350 is tented across the cavity 307 is shown, in accordance with an embodiment. The resist layer 350 may be any suitable resist material, such as a dry film resist (DFR) or the like. The resist layer 350 may be applied over the package substrate 300 with a lamination process (e.g., a hot roller lamination). As shown, the resist layer 350 may cover the top opening of the cavity 307. A bottom surface 351 of the resist layer 350 may sag into the cavity 307 in some embodiments. However, the resist layer 350 may not completely fill the cavity 307. For example, a bottom surface and portions of the sidewalls of the cavity 307 may not be covered by the resist layer 350.

Referring now to FIG. 3H, a cross-sectional illustration of the portion of the package substrate 300 after a lithography process is used to form an opening 355 in the resist layer 350 is shown, in accordance with an embodiment. In an embodiment, the resist layer 350 may be patterned with any suitable lithography process in order to form the opening 355. The opening 355 may be provided within the outer edges of the cavity 307. That is, the opening 355 may be narrower than a maximum width of the cavity 307 in some embodiments. Accordingly, portions of the resist layer 350 may remain within the cavity 307. More particularly, the resist layer 350 may cover upper portions of the sidewalls of the cavity 307.

Referring now to FIG. 3I, a cross-sectional illustration of the portion of the package substrate 300 after a spacer layer 310 is formed is shown, in accordance with an embodiment. In an embodiment, the spacer layer 310 may be formed with a plating process, such as an electroplating process. The resist layer 350 prevents plating over the remainder of the package substrate 300, and the spacer layer 310 is confined towards a lower portion of the cavity 307. In an embodiment, the spacer layer 310 may have a bowl shaped cross-section. The spacer layer 310 may comprise a first portion 311 along the bottom of the cavity 307 and second portions 312 that extend up sidewalls of the cavity 307. The second portions 312 may extend up to the bottom of the resist layer 350.

Referring now to FIG. 3J, a cross-sectional illustration of the portion of the package substrate 300 after the resist layer 350 is removed is shown, in accordance with an embodiment. In an embodiment, the resist layer 350 may be removed with any suitable resist stripping process, etching process, or the like. Removal of the resist layer 350 may expose the regions of the seed layer 345 that were not plated during the formation of the spacer layer 310.

Referring now to FIG. 3K, a cross-sectional illustration of the portion of the package substrate 300 after the seed layer 345 is etched back is shown, in accordance with an embodiment. The exposed portions of the seed layer 345 may be removed with a wet etching process or the like. The short duration of the etch may not substantially alter the structure of the spacer layer 310.

Referring now to FIG. 3L, a cross-sectional illustration of the portion of the package substrate 300 after a component 320 is placed in the cavity 307 is shown, in accordance with an embodiment. In an embodiment, the component 320 may be placed onto the spacer layer 310 with a pick-and-place tool, manually, or with any other suitable transfer process. The component 320 may be coupled to the first portion 311 of the spacer layer 310 by an adhesive layer 323 or the like. The component 320 may be a passive electrical component. For example, the component 320 may comprise one or more of an inductor, a capacitor, or a resistor. Pads 322 may be provided at a top of the component 320. The component 320 may be similar to any of the components described in greater detail herein.

Referring now to FIG. 3M, a cross-sectional illustration of the portion of the package substrate 300 after a fill layer 328 is provided within the cavity 307 is shown, in accordance with an embodiment. The fill layer 328 may be a buildup film or other organic dielectric material. The fill layer 328 may cover sidewalls of the component 320 and a top surface of the component 320. The fill layer 328 may be the same material as the buildup layers 341. In some embodiments, the fill layer 328 may be applied with a lamination process or the like.

Referring now to FIG. 3N, a cross-sectional illustration of the portion of the electronic package 300 after via openings 357 are formed through the fill layer 328 is shown, in accordance with an embodiment. In an embodiment, the via openings 357 are formed with a laser ablation process. Though, any suitable subtractive process may be used in order to form the via openings 357.

Referring now to FIG. 3O, a cross-sectional illustration of the portion of the electronic package 300 after the vias 325 and pads 326 are formed over the component 320 is shown, in accordance with an embodiment. In an embodiment, the vias 325 and pads 326 may be plated or deposited with any suitable process. The vias 325 may land on the pads 322 of the component 320. As such, the component 320 can be electrically coupled to other devices or components within (or coupled to) the package substrate 300.

Referring now to FIG. 3P, a process flow diagram of a process 360 for embedding a component in a cavity of a package substrate using a tenting process. In an embodiment, the process 360 may begin with operation 361, which comprises forming a cavity through a core. The operation 361 may include structures and processes similar to those described herein with respect to FIGS. 3A-3E.

In an embodiment, the process 360 may continue with operation 362, which comprises applying a resist layer over the core, where the resist layer tents across the cavity. The operation 362 may include structures and processes similar to those described herein with respect to FIG. 3F-3G.

In an embodiment, the process 360 may continue with operation 363, which comprises forming an opening through the resist layer. The operation 363 may include structures and processes similar to those described herein with respect to FIG. 3H.

In an embodiment, the process 360 may continue with operation 364, which comprises plating a pad at a bottom of the cavity. In an embodiment, the pad extends partially up sidewalls of the cavity. The operation 364 may include structures and processes similar to those described herein with respect to FIG. 3I.

In an embodiment, the process 360 may continue with operation 365, which comprises removing the resist layer. The operation 365 may include structures and processes similar to those described herein with respect to FIG. 3J.

In an embodiment, the process 360 may continue with operation 366, which comprises placing a component on the pad. The operation 366 may include structures and processes similar to those described herein with respect to FIGS. 3K-3L.

In an embodiment, the process 360 may continue with operation 367, which comprises filling the cavity with a fill layer. The operation 367 may include structures and processes similar to those described herein with respect to FIGS. 3M-3O.

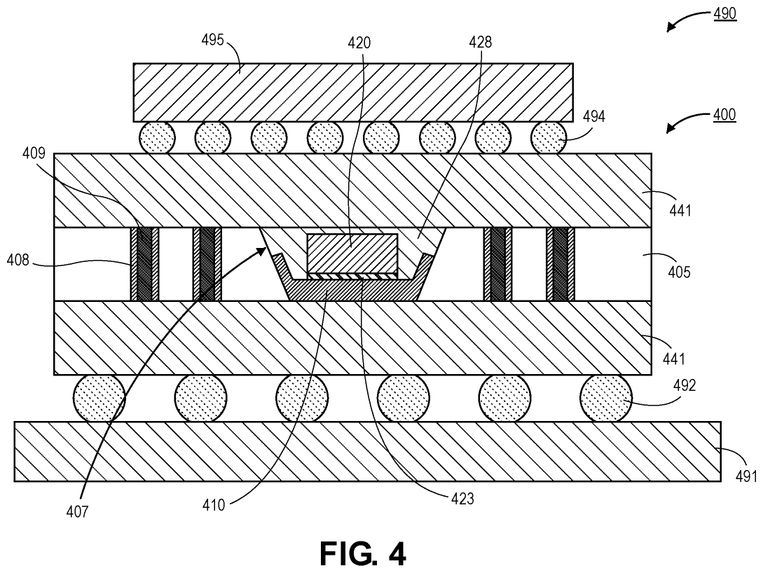

Referring now to FIG. 4, a cross-sectional illustration of an electronic system 490 is shown, in accordance with an embodiment. In an embodiment, the electronic system 490 comprises a board, such as a printed circuit board (PCB), a motherboard, or the like. In an embodiment, the board 490 is coupled to a package substrate 400 by interconnects 492. The interconnects 492 may be second level interconnects (SLIs), such as solder balls, sockets, pins, or the like.

In an embodiment, the package substrate 400 may be similar to any of the package substrates described herein. For example, the package substrate 400 may include a core 405 (e.g., a glass core 405 or an organic core 405) with buildup layers 441 above and below the core 405. The core 405 may comprise vias 408. In FIG. 4, the vias 408 are filled with an insulating plug 409. A cavity 407 may be provided through a thickness of the core 405.

In an embodiment, a component 420 may be set into the cavity 407. For example, the component 420 may be supported by a spacer layer 410 within the cavity 407. An adhesive layer 423 may couple the component 420 to the spacer layer 410. The spacer layer 410 may comprise copper or another metallic material. In an embodiment, the spacer layer 410 has a bowl shaped cross-section with arms that extend partially up sidewalls of the cavity 407. A fill layer 428 surrounds the component 420 and fills a remaining portion of the cavity 407.

In an embodiment, one or more dies 495 may be coupled to the package substrate 400 by interconnects 494. The interconnects 494 may comprise first level interconnects (FLIs), such as solder balls, copper bumps, hybrid bonding interfaces, or the like. The die 495 may be any type of die, such as a central processing unit (CPU), a graphics processing unit (GPU), an XPU, a communications die, a memory die, an application specific integrated circuit (ASIC), a field programmable gate array (FPGA), or the like. In an embodiment, the component 420 is electrically coupled to the one or more dies 495 in order to control and/or improve power delivery that is provided to the die 495.

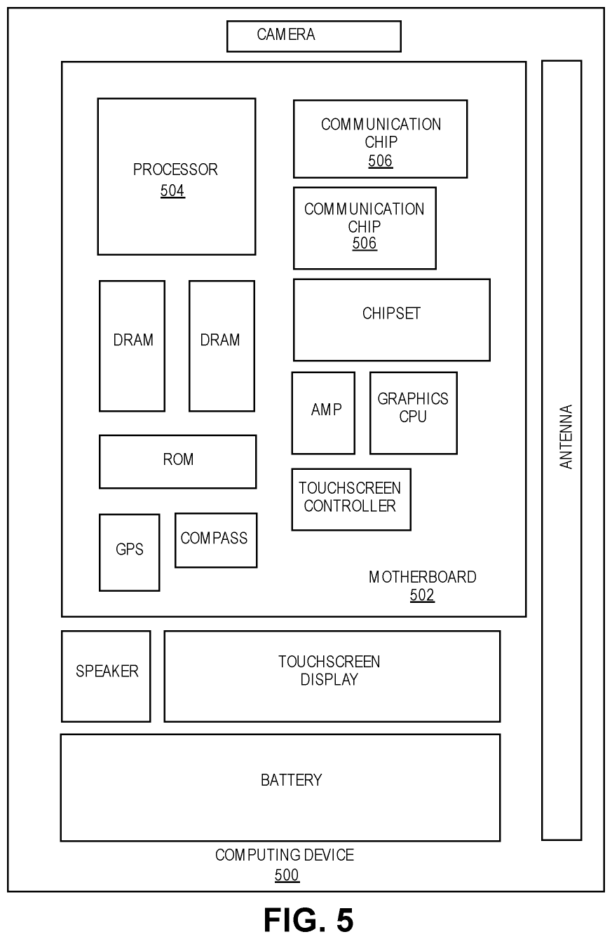

FIG. 5 illustrates a computing device 500 in accordance with one implementation of the disclosure. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the disclosure, the integrated circuit die of the processor may be part of an electronic package that includes a core with a cavity, and a passive electrical component is supported by a spacer layer within the cavity, in accordance with embodiments described herein. The term “processor” may refer to any device or portion of a device that processes electronic data from registers and/or memory to transform that electronic data into other electronic data that may be stored in registers and/or memory.

The communication chip 506 also includes an integrated circuit die packaged within the communication chip 506. In accordance with another implementation of the disclosure, the integrated circuit die of the communication chip may be part of an electronic package that includes core with a cavity, and a passive electrical component is supported by a spacer layer within the cavity, in accordance with embodiments described herein.

In an embodiment, the computing device 500 may be part of any apparatus. For example, the computing device may be part of a personal computer, a server, a mobile device, a tablet, an automobile, or the like. That is, the computing device 500 is not limited to being used for any particular type of system, and the computing device 500 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate; a cavity through a thickness of the substrate, wherein the cavity comprises sidewalls; a layer that spans an opening of the cavity, and wherein the layer covers at least a portion of the sidewalls of the cavity; and a component coupled to the layer, wherein the component is at least partially within the cavity.

Example 2: the apparatus of Example 1, wherein the layer comprises: a first portion with a first surface that is substantially parallel to a surface of the substrate; and a second portion with a second surface that contacts the sidewall of the cavity, and wherein the second surface is on a first plane that intersects a second plane comprising the surface of the substrate.

Example 3: the apparatus of Example 2, wherein a width of the first portion is greater than a width of the component.

Example 4: the apparatus of Examples 1-3, wherein the layer comprises: a seed layer; and a bulk layer.

Example 5: the apparatus of Examples 1-4, wherein the layer covers up to one-half of a total height of the sidewalls of the cavity.

Example 6: the apparatus of Examples 1-5, wherein the component is coupled to the layer by an adhesive.

Example 7: the apparatus of Examples 1-6, wherein the component comprises one or more of an inductor, a capacitor, or a resistor.

Example 8: the apparatus of Examples 1-7, wherein the sidewalls of the cavity are sloped so that they are non-orthogonal with a top surface of the substrate.

Example 9: the apparatus of Examples 1-8, wherein the substrate comprises an organic dielectric material or a glass substrate with a rectangular prism form factor.

Example 10: the apparatus of Examples 1-9, further comprising: a fill layer around the component.

Example 11: an apparatus, comprising: a substrate; a cavity through a thickness of the substrate; a first layer that seals an opening of the cavity, wherein the first layer has a bowl shaped cross-section that extends up sidewalls of the cavity; a component coupled to the layer; and a second layer around the component within the cavity.

Example 12: the apparatus of Example 11, wherein the first layer comprises: a first portion, wherein the first portion has surfaces that are substantially parallel to a top surface of the substrate; and a second portion, wherein the second portion has a surface that is on a first plane that intersects a second plane that comprises the top surface of the substrate.

Example 13: the apparatus of Example 11 or Example 12, wherein the component comprises one or more of an inductor, a capacitor, or a resistor.

Example 14: the apparatus of Examples 11-13, wherein the first layer comprises: a seed layer; and a metallic layer comprising copper.

Example 15: the apparatus of Examples 11-14, wherein a first distance between an uppermost point of the first layer and a plane comprising a top surface of the substrate is larger than a second distance between a top surface of the component and the plane comprising the top surface of the substrate.

Example 16: the apparatus of Examples 11-15, further comprising: a second component on the first layer within the cavity.

Example 17: an apparatus, comprising: a board; a package substrate coupled to the board, wherein the package substrate comprises: a core; a cavity through a thickness of the core; a first layer that spans an opening of the cavity and extends up sidewalls of the cavity; and a component coupled to the first layer, wherein the component is at least partially within the cavity; and a die coupled to the package substrate.

Example 18: the apparatus of Example 17, wherein the component comprises one or more of an inductor, a capacitor, or a resistor.

Example 19: the apparatus of Example 17 or Example 18, wherein the first layer comprises copper.

Example 20: the apparatus of Examples 17-19, wherein the apparatus is part of a personal computer, a server, a mobile device, a tablet, or an automobile.

What is claimed is:

1. An apparatus, comprising:
a substrate;
a cavity through a thickness of the substrate, wherein the cavity comprises sidewalls;
a layer that spans an opening of the cavity, and wherein the layer covers at least a portion of the sidewalls of the cavity; and
a component coupled to the layer, wherein the component is at least partially within the cavity.

2. The apparatus of claim 1, wherein the layer comprises:
a first portion with a first surface that is substantially parallel to a surface of the substrate; and
a second portion with a second surface that contacts the sidewall of the cavity, and wherein the second surface is on a first plane that intersects a second plane comprising the surface of the substrate.

3. The apparatus of claim 2, wherein a width of the first portion is greater than a width of the component.

4. The apparatus of claim 1, wherein the layer comprises:
a seed layer; and
a bulk layer.

5. The apparatus of claim 1, wherein the layer covers up to one-half of a total height of the sidewalls of the cavity.

6. The apparatus of claim 1, wherein the component is coupled to the layer by an adhesive.

7. The apparatus of claim 1, wherein the component comprises one or more of an inductor, a capacitor, or a resistor.

8. The apparatus of claim 1, wherein the sidewalls of the cavity are sloped so that they are non-orthogonal with a top surface of the substrate.

9. The apparatus of claim 1, wherein the substrate comprises an organic dielectric material or a glass substrate with a rectangular prism form factor.

10. The apparatus of claim 1, further comprising:
a fill layer around the component.

11. An apparatus, comprising:
a substrate;
a cavity through a thickness of the substrate;
a first layer that seals an opening of the cavity, wherein the first layer has a bowl shaped cross-section that extends up sidewalls of the cavity;
a component coupled to the layer; and
a second layer around the component within the cavity.

12. The apparatus of claim 11, wherein the first layer comprises:
a first portion, wherein the first portion has surfaces that are substantially parallel to a top surface of the substrate; and
a second portion, wherein the second portion has a surface that is on a first plane that intersects a second plane that comprises the top surface of the substrate.

13. The apparatus of claim 11, wherein the component comprises one or more of an inductor, a capacitor, or a resistor.

14. The apparatus of claim 11, wherein the first layer comprises:
a seed layer; and
a metallic layer comprising copper.

15. The apparatus of claim 11, wherein a first distance between an uppermost point of the first layer and a plane comprising a top surface of the substrate is larger than a second distance between a top surface of the component and the plane comprising the top surface of the substrate.

16. The apparatus of claim 11, further comprising:
a second component on the first layer within the cavity.

17. An apparatus, comprising:
a board;
a package substrate coupled to the board, wherein the package substrate comprises:
a core;
a cavity through a thickness of the core;
a first layer that spans an opening of the cavity and extends up sidewalls of the cavity; and
a component coupled to the first layer, wherein the component is at least partially within the cavity; and
a die coupled to the package substrate.

18. The apparatus of claim 17, wherein the component comprises one or more of an inductor, a capacitor, or a resistor.

19. The apparatus of claim 17, wherein the first layer comprises copper.

20. The apparatus of claim 17, wherein the apparatus is part of a personal computer, a server, a mobile device, a tablet, or an automobile.
